(19) United States
(12) Patent Application Publication
(10) Pub. No.: US 2023/0352369 A1
(43) Pub. Date: Nov. 2, 2023

(54) THROUGH-SUBSTRATE VIAS WITH METAL PLANE LAYERS AND METHODS OF MANUFACTURING THE SAME

(71) Applicant: Invensas Bonding Technologies, Inc., San Jose, CA (US)

(72) Inventors: Gaius Gillman Fountain, JR., Youngsville, NC (US); George Carlton Hudson, Wendell, NC (US)

(21) Appl. No.: 17/731,847

(22) Filed: Apr. 28, 2022

(51) Int. Cl. H01L 23/48; H01L 23/532; H01L 21/768

(52) U.S. Cl. CPC H01L 23/481; H01L 23/53238; H01L 21/76898; H01L 21/7684

(57) ABSTRACT

Embodiments herein include post-TSV reveal processing methods and devices formed using the methods. In some embodiments, the methods include forming an electrically and thermally conductive layer on the device that may be used as a power/ground connection path or a thermal spreading plane in a device assembly that includes a plurality of interconnected stacked devices.

### FIELD

The present disclosure generally relates to semiconductor device manufacturing and assembly and, more particularly, to electronic device assemblies formed using through-substrate vias (TSVs) and methods of forming the device assemblies.

### BACKGROUND

A through-substrate via (TSV) is a conductive feature disposed completely through a substrate, such as from a device side or “active” surface to a non-device side or “backside” surface of a silicon wafer, i.e., a “through-silicon via,” which may be used to provide electrical connections between individual devices. TSVs allow for substantially increased density and substantially decreased length of inter-device connections as compared to conventional connections, e.g., wire-bond or flip-chip connections. Thus, TSVs are increasingly relied upon in multi-device integration schemes to meet the seemingly endless drive for reduced power consumption and smaller electronic device packaging, such as TSVs used for power delivery or inter-device communication in a three-dimensional integrated circuit (3D-IC) device assembly scheme.

TSVs are commonly formed within the boundaries of a die using a via-first, via-middle, or via-last fabrication scheme. Generally, in via-first and via-middle fabrication schemes, conductive features that will become the TSVs are first formed in a device-side surface of the substrate to extend into the substrate in the thickness direction but not all the way through, i.e., “blind vias.” In a via-first scheme, the blind vias are formed before front-end-of-line (FEOL) fabrication of individual device elements, e.g., transistors, resistors, and capacitors. In a via-middle scheme, the blind vias are formed after FEOL processes and before back-end-of-line (BEOL) fabrication of metal interconnects. Generally, with either scheme, the base surfaces of the blind vias are exposed once fabrication of the device is substantially complete, e.g., during post-fabrication device assembly and test operations. Exposing the base surfaces of the blind vias includes removing material from the non-device side surface of the substrate using a series of substrate thinning operations, collectively referred to as TSV reveal.

Unfortunately, processing non-uniformities in the formation of blind vias and relatively narrow processing windows at TSV reveal often combine to cause significant connection defects at device assembly and test operations. Such non-uniformities may include variations in the blind vias formed within a device (within-die non-uniformities), across a substrate (within-substrate non-uniformities), and/or between devices formed on different substrates (substrate-to-substrate non-uniformities). Problems associated with blind via non-uniformities are further compounded at outsourced assembly and test (OSAT) facilities, which receive and assemble devices from different device manufacturers. The compounding effects of processing non-uniformities and the resulting connection defects frequently result in failure of the packaged device assembly, thus reducing yield and increasing overall manufacturing costs. As a result, advanced integration technologies that use TSV interconnections, e.g., three-dimensional integrated circuits (3D-ICs), have not yet reached widespread commercial viability. Accordingly, there is a need for improved and more robust TSV reveal and post-reveal methods with wider processing windows that account for incoming variation in blind vias formed in a via-first or via-middle TSV fabrication scheme.

### SUMMARY

Embodiments herein include post-TSV reveal processing methods and devices formed using the methods. In some embodiments, the methods include forming an electrically and thermally conductive layer on the device that may be used as a power/ground connection path or a thermal spreading plane in a device assembly that includes a plurality of interconnected stacked devices.

In one embodiment, a method for forming a conductive plane around a via pillar that protrudes from a surface of a substrate is provided. The method includes forming a support layer stack comprising a metal plane layer and a first dielectric layer disposed on the metal plane layer. Here, the metal plane layer surrounds at least a base portion of the via pillar, and the first dielectric layer covers an upwardly facing surface of the via pillar. The method further includes using a polishing process to remove a first portion of the first dielectric layer and a portion of the via pillar to expose a surface of the metal via. Here, the surface of the metal via is surrounded by a second portion of the first dielectric layer, which remains after the polishing process. In some embodiments, one or more second dielectric layers may be disposed between the metal plane layer and the non-active surface of the substrate and between the metal plane layer and the base portion of the via pillar. In some embodiments, the substrate comprises a semiconductor portion, the metal via extends through the semiconductor portion, and a dielectric liner is disposed between the metal via and the semiconductor portion and between the metal via and the one or more second dielectric layers.

In some embodiments, forming the metal plane layer includes depositing a metal support layer and recessing a surface of the metal support layer below the upwardly facing surface of the via pillar. Recessing the surface of the metal layer may include removing a portion of the metal layer by use of a polishing process, an etch process, or a combination thereof. In some embodiments, the metal plane layer forms a ground or power plane of a power distribution network to two or more interconnected devices.

In another embodiment, a method for forming uniform through-substrate vias in a microelectronic device is provided. The method may include depositing a support layer to surround a plurality of via pillars that protrude from a surface of a substrate and exposing an upwardly facing surface of each of the through-substrate vias by removing the support layer and the plurality of via pillars. In some embodiments, the support layer is deposited to a thickness that is greater than the height of the plurality of via pillars. In some embodiments, the support layer is removed using a polishing process. In some embodiments, the support layer is formed of a metal or metal alloy. In some embodiments, the metal may include copper, tungsten, nickel, mixtures thereof, and/or alloys thereof. In some embodiments, the exposed via surface may be formed of one or more of the same metals as used to form the support layer.

In another embodiment, a microelectronic structure is provided. The microelectronic structure may include a semiconductor substrate having a first surface and a second surface opposite the first surface, a first dielectric layer disposed on the first surface, and a via structure disposed through the first dielectric layer. Here, the via structure is at least partially disposed through the semiconductor substrate so that at least a portion of the via structure protrudes above the first dielectric layer to define a via pillar. The microelectronic structure may further include a metal plane layer disposed on the first dielectric layer and a second dielectric layer disposed on the metal plane layer. In some embodiments, the via structure is formed of a conductive material that is electrically isolated from the metal plane layer by a portion of a dielectric liner disposed therebetween. In some embodiments, the metal plane layer is formed of a material selected from the group consisting of copper, tungsten, nickel, mixtures thereof, and/or alloys thereof.

In some embodiments, the metal plane layer is coupled to an external power supply. In some embodiments, the metal plane layer is coupled to a ground connection path. In some embodiments, the metal plane layer forms a bias plane of a packaged electronic device.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1F are cross-sectional views illustrating the formation of blind vias in a via-first or via-middle process.

FIG. 2 is a diagram of a method that may be used to form one or more of the devices shown in FIGS. 1A-1, according to some embodiments.

FIGS. 3A-3E are schematic cross-sectional views of a substrate at different stages of the method set forth in FIG. 2, according to some embodiments.

FIG. 4 is a block diagram of a method that may be used to form one or more of the devices shown in FIG. 1C, according to some embodiments.

FIGS. 5A-5B are schematic cross-sectional views of a substrate at different stages of the method set forth in FIG. 4, according to some embodiments.

FIGS. 6 and 7 are schematic cross-sectional views of device assemblies formed according to some embodiments.

The figures herein depict various embodiments of the invention for purposes of illustration only. It will be appreciated that additional or alternative structures, systems and methods may be implemented within the principles set out by the present disclosure.

### DETAILED DESCRIPTION

Embodiments provided herein are directed to methods for substantially reducing and/or eliminating processing defects in a through-substrate via (TSV) reveal process and devices formed using the methods. In some embodiments, the methods may be advantageously used to substantially reduce TSV breakage during one or more post-reveal chemical mechanical polishing (CMP) processes, caused by incoming variations in blind vias formed using a via-first or via-middle TSV fabrication scheme. In some embodiments, the methods include forming an electrically and thermally conductive layer on the device that may be used as a power/ground connection path or a thermal spreading plane in a device assembly that includes a plurality of interconnected stacked devices.

As used herein, the term “substrate” includes any workpiece that provides a supporting material upon which elements of a semiconductor device are fabricated or attached and any material layers, features, and/or electronic devices formed thereon, therein, or therethrough. Thus, the term substrate includes both the semiconductor substrate upon which device elements are fabricated and the reduced thickness semiconductor substrate, material layers, devices, and features formed on, in, or through the semiconductor substrate when fabrication and/or assembly is complete. It should also be understood that the term substrate as used herein further includes any material layers, devices, and features formed on, in, or through the semiconductor substrate at any point in the device fabrication and assembly process, whether or not the material layers, devices, or features are present in the finished device or assembly.

As described below, the substrates herein generally have a “device side,” e.g., the side on which semiconductor device elements are fabricated, such as transistors, resistors, and capacitors, and a “backside” that is opposite the device side. The term “active surface” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active surface may change depending on the stage of device fabrication and assembly. Similarly, the term “non-active surface” (opposite the active surface) includes the non-active surface of the substrate at any stage of device fabrication, including the surfaces of any material layer, any feature formed thereon, or extending outwardly therefrom, and/or any openings formed therein. Thus, the terms “active surface” or “non-active surface” may include the respective surfaces of the semiconductor substrate at the beginning of device fabrication and any surfaces formed during material removal, e.g., after substrate thinning operations. Depending on the stage of device fabrication or assembly, the terms “active” and “non-active surfaces” are also used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between the semiconductor substrate and the individual material layers, devices, and features described below. Unless the relationship is otherwise defined, terms such as “above,” “over,” “upper,” “upwardly,” “outwardly,” “on,” “below,” “under,” “beneath,” “lower,” and the like are generally made with reference to the active or non-active surface of the semiconductor substrate and/or material layers disposed thereon. Thus, it should be understood that the spatially relative terms used herein are intended to encompass different orientations of the substrate and, unless otherwise noted, are not limited by the direction of gravity. Terms describing the relationships between elements such as “disposed on,” “embedded in,” “coupled to,” “connected by,” either alone or in combination with a spatially relevant term include both relationships within intervening elements and direct relationships where there are no intervening elements.

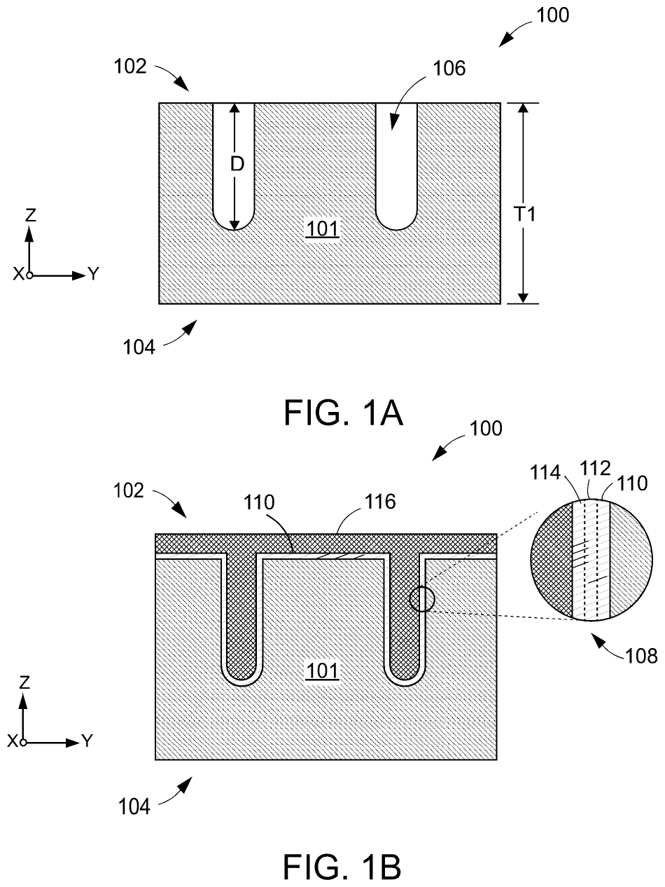

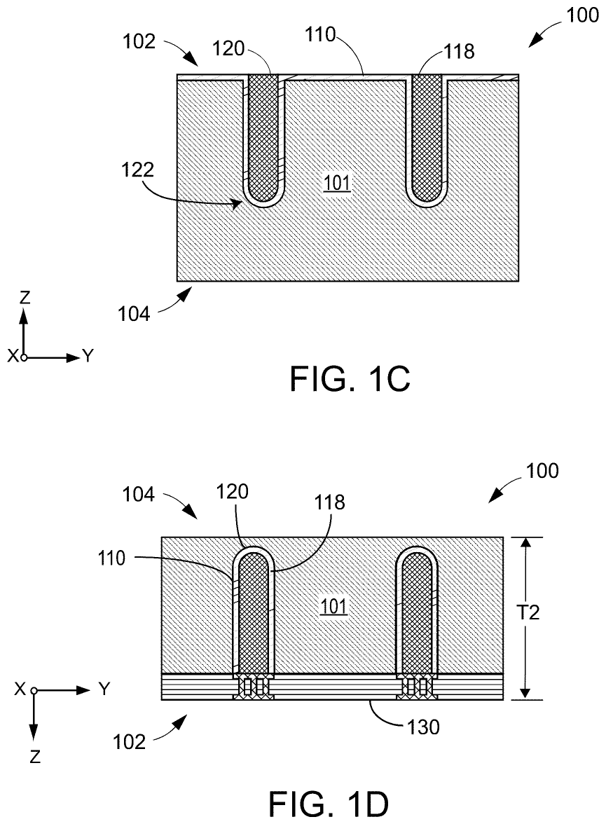

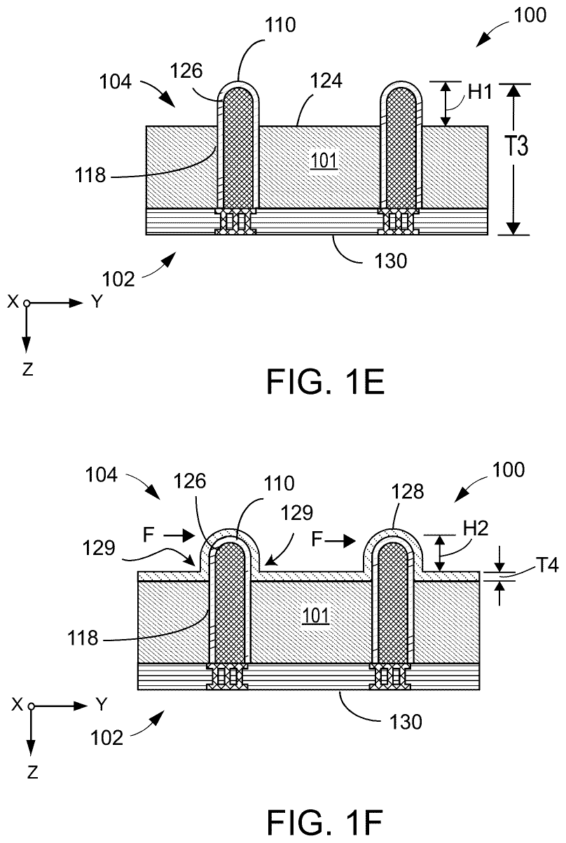

FIGS. 1A-1F schematically illustrate the formation of blind vias in an active surface 102 of a substrate 100 and the reveal of via pillars 126 (FIG. 1E) from the non-active surface 104 in a via-first or via-middle processing scheme. It is contemplated that the processes illustrated in FIGS. 1A-1F may be used in combination with any of the methods described herein to form a through-substrate via (TSV). Here, the substrate 100 includes a semiconductor substrate 101 formed of a group IV semiconductor, such as silicon, silicon germanium or germanium, a III-V compound semiconductor, or a II-VI semiconductor and any device elements formed or partially formed thereon. In some embodiments, the semiconductor substrate 101 may be formed of a group IV semiconductor, such as silicon, silicon germanium or germanium; a III-V compound semiconductor; or a II-VI semiconductor. In some embodiments, such as via-middle processing schemes, the substrate 100 may include one or a combination of device elements, such as transistors, capacitors, or resistors formed on or in the active surface 102. To avoid overcomplicating the drawings, such devices are not shown here.

As shown in FIG. 1A, forming a via-first or via-middle TSV typically includes forming a high aspect ratio opening 106 in the active surface 102 of the substrate 100, where the opening 106 is formed to a depth D in the thickness direction of the substrate 100 (Z-direction) but does not extend all the way through to the inactive surface 104. In some embodiments, the depth D of the opening 106 may be between about 50 um and about 200 um, and a thickness T1 of the substrate 100 may be between about 600 um and about 1000 um.

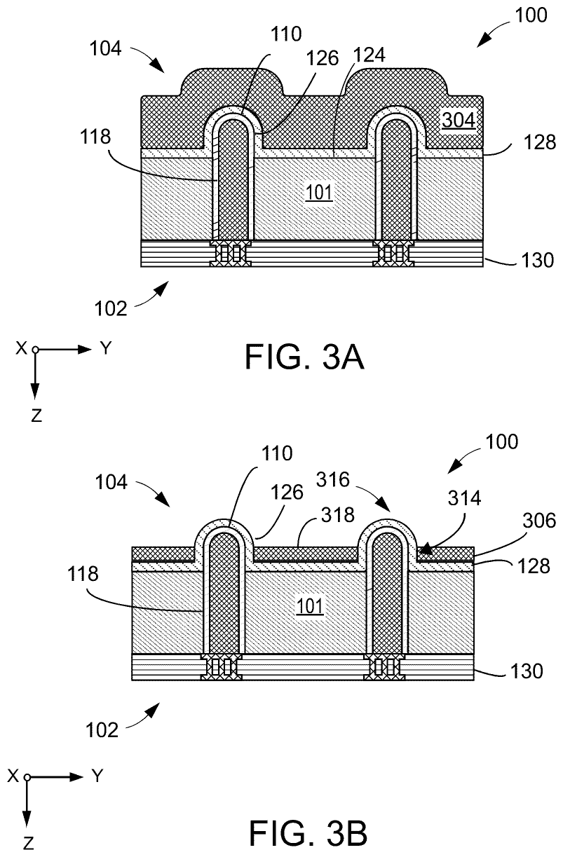

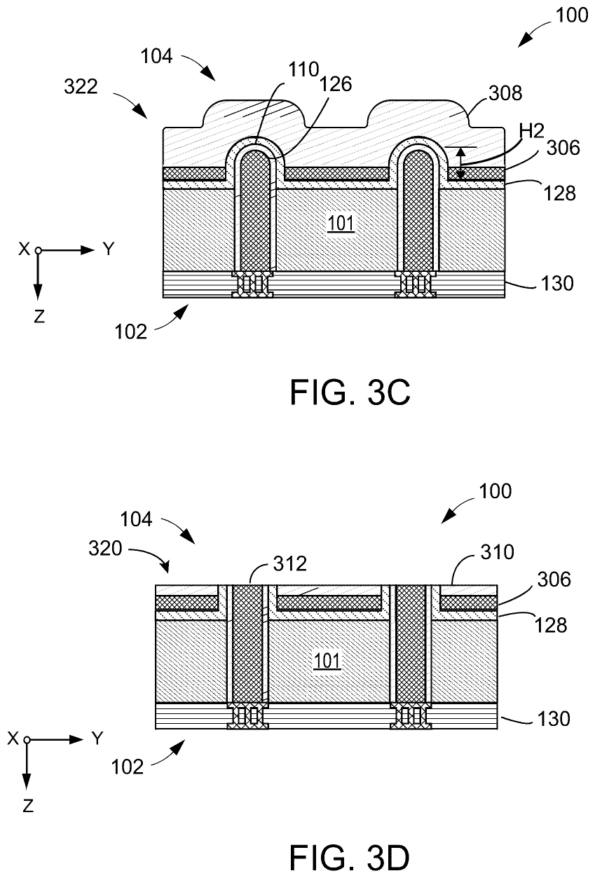

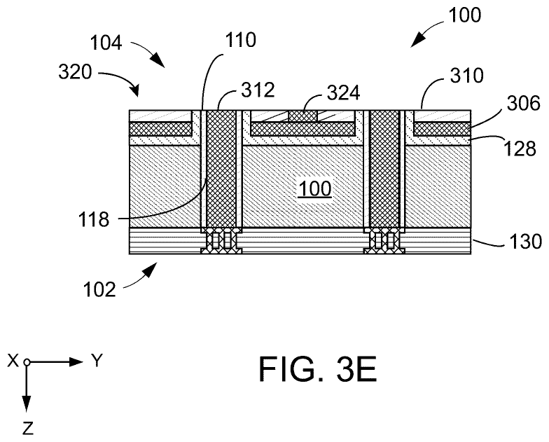

In FIG. 1B, one or more barrier layers 108 are deposited to line the walls and base surface of the opening 106, and a conductive material 116 is deposited on the barrier layers 108 to fill the remaining portion of the opening 106 and form a conductive via feature 118 (FIG. 3C). In some embodiments, the conductive material 116 comprises copper, a copper alloy tungsten, a tungsten alloy, and/or mixtures, alloys, and combinations thereof. Here, copper alloys and tungsten alloys include mixtures of copper and/or tungsten with other metals that will form an alloy upon annealing.

The barrier layers 108 may be used to prevent undesired diffusion of the conductive material 116 into the surrounding material of the semiconductor substrate 101, provide an adhesion interface layer between the conductive material and the walls and base surfaces of the openings 106, and/or facilitate subsequent deposition of the conductive material 116. For example, the barrier layers 108 may include a dielectric material layer 110, one or more metal or metal nitride layers 112 deposited on the dielectric material layer 110, and a seed material layer 114 deposited on the one or more metal or metal nitride layers 112, each of which are shown in FIG. 1B. Examples of materials that may be used for the dielectric material layer 110 include silicon oxides (Si_{X}O_{Y}), silicon nitrides (SiN_{X}), silicon oxynitrides (Si_{X}O_{Y}N_{Z}, silicon carbides (SiC), aluminum oxide (Al_{X}O_{Y}), and combinations thereof. Examples of materials that may be used as the metal or metal nitride layers 112 include Ti, Ta, W, TiN, TaN, WN, and combinations thereof.

In some embodiments the seed material layer 114 is formed of the same metal as the conductive material 116 used to fill the openings 106, e.g., to facilitate electrodeposition of the conductive material 116. For example, in some embodiments, the seed material layer 114 may include copper, a mixture of metals that includes copper, and/or a copper alloy. In other embodiments, the seed material layer 114 may include a different material, such as Co, Ru, Mn, Ti, Ta, W, or combinations thereof. In order to reduce visual clutter, only the dielectric material layer 110 of the one or more barrier layers 108 is shown in the remaining FIGS.

In FIG. 1C, an overburden of the conductive material 116 is removed from the field of the active surface 102, e.g., by use of a CMP process, before the substrate 100 is sent for further device fabrication processing. Typically, the base surface 122 of each blind via 120 is exposed when the semiconductor substrate 101 is thinned in preparation for device assembly, such as in the TSV reveal process illustrated in FIGS. 1D-1F, which may be used in combination with any of the methods described below. Once thinned, the substrate 100 may be difficult to handle due to warp and bow caused by the substrate thinning processes and imparted by cumulative intrinsic stresses in the material layer stack that forms the active surface 102. Thus, to facilitate substrate handling, the active surface 102 of the substrate 100 may be temporarily bonded to a second “carrier substrate” (not shown) that provides structural support during the TSV reveal and post-reveal processing methods described herein. The substrate 100 may be bonded to the carrier substrate before or after substrate thinning and may be removed, if at all, before or after singulation of the individual devices formed on the substrate 100.

FIGS. 1D-1F schematically illustrate a via reveal process performed after device fabrication is substantially complete, e.g., after interconnect layers 130 are formed in the active surface 102 of the substrate 100 during BEOL fabrication. Here, the reveal process includes a bulk material removal process to thin the substrate 100 to a thickness T2 (FIG. 1D), followed by a selective material removal process to thin the substrate 100 to a thickness T3 (FIG. 1E). The bulk material removal process typically includes a backgrind process and an optional CMP process that uniformly removes semiconductor material from the non-active surface 104 up to the thickness T2. The thickness T2 may be selected based on the depth D of the openings 106 formed in the active surface 102 so as to not expose the base surfaces 122 of the blind vias 120.

The base surfaces 122 are revealed during the selective material removal process, such as a wet etch process, a plasma-based (dry) etch process, a CMP process, or a combination thereof. Typically, the semiconductor material is selectively removed from the backside of the semiconductor substrate 101 with respect to the dielectric material layer 110 so that the conductive material 116 there beneath is not exposed during the reveal process. The selective material removal process protects the non-active surface 104 of the semiconductor substrate 101 from contamination that would occur if the semiconductor substrate 101 were exposed to the conductive material 116 during the reveal process. Thus, as shown in FIG. 1E, the non-active surface 104 of the semiconductor substrate 101 (recessed surface 124) is recessed below a portion of the (previously) blind via 120, which protrudes above the recessed surface 124 to form a via pillar 126 having a height H1. The via pillar 126 includes a protruding portion of the via feature 118 and the barrier layers 108, including the dielectric material layer(s) 110, disposed thereover. In some embodiments, an average height H1 of via pillars 126 across the non-active surface is between about 1 um an about 10 um, such as between about 1 um and about 5 um, and a difference in H1 between different via pillars 126 may range from about 1 um to about 5 um.

Typically, one or more dielectric material layers 128, such as a one or more layers of a silicon oxide, silicon nitride, silicon oxynitride, or a combination thereof, are deposited on the recessed surface 124 and the via pillars 126 protruding upwardly therefrom. The one or more dielectric material layers 128 form a passivation and/or isolation layer on the recessed surface 124 that protects the recessed surface 124 of the semiconductor substrate 101 from damage or contamination caused by exposure to atmospheric conditions and/or subsequent substrate processing operations. In some embodiments, one or more dielectric material layers 128 are used to facilitate a direct-bond device assembly method, such as described in the methods below. Typically, the dielectric material layers 110 and 128 that cover the conductive material 116 of the pillar 126 are removed prior to device assembly to form a suitable TSV contact and/or bonding surface, such as by use of a planarizing CMP process. In those embodiments, the dielectric material layer 128 protects the recessed surface from contamination from the conductive material, e.g., copper, exposed during the planarizing CMP process. In some embodiments, the dielectric material layer(s) 128 include a silicon oxide layer deposited on a silicon nitride layer, or vice versa. As shown in FIG. 1F, the dielectric material layer(s) 128 are deposited to a combined thickness T4, such as between about 0.5 um and about 3 um, that is less than the height H1 of the pillars 126 as measured from the recessed surface 124.

Generally, the planarizing CMP process includes urging the non-active surface 104 of the substrate 100 against a polishing pad surface (not shown) in the presence of a polishing slurry. Urging the non-active surface 104 against a polishing surface may include applying a force against the substrate 100 towards the polishing surface, e.g., in the Z direction while moving the substrate 100 and the polishing surface relative to one another in the X-Y plane (orthogonal to the Z-direction). Mechanical forces from the relative motion of the non-active surface 104, the polishing pad, and slurry abrasives at the polishing interface and chemical reactions between the polishing slurry and the non-active surface 104 combine to planarize the surface, i.e., to remove the protruding portions of the via pillars 126 therefrom. Unfortunately, lateral forces F (shown in FIG. 1F) exerted against the TSV pillars 126 from the combined lateral motion and applied force in the Z-direction can contribute to undesirable pillar breakage or “pillar knockdown” of portions of the TSV and/or the dielectric material layer 128. The pillar breakage and/or other defects, such as cracking of the dielectric material layer 128, often occur at or below a principle stress point 129 proximate to the recessed surface 124. Such defects can result in missed electrical connections between devices and thus device failure upon assembly. Generally, such defects increase with increasing pillar height, likely due to the increased moment about the principle stress point 129. As a result, the process window for material removal during the selective material removal process at TSV reveal is fairly narrow as a larger window that allows for increased variation in pillar height typically results in increased pillar breakage and cracking defects. Accordingly, the methods provided herein include removing at least a portion of a pillar 126 from the non-active surface 104 while concurrently protecting the pillars 126 from lateral polishing forces exerted during the removal process.

In some embodiments, the via pillars 126 are protected from lateral polishing forces by one or more pillar support layers that surround the pillars 126 in the X-Y plane (orthogonal to the thickness direction Z), such as illustrated in FIG. shown in FIG. 3C. In those embodiments, the lateral polishing forces that might otherwise cause undesirable breakage of individual via pillars 126 are redistributed across the surface of the support layers at the polishing interface. Thus, the one or more pillar support layers beneficially provide for controlled and uniform planarization of both the pillar support layer and the outwardly facing surfaces of the TSV pillars 126 disposed therein.

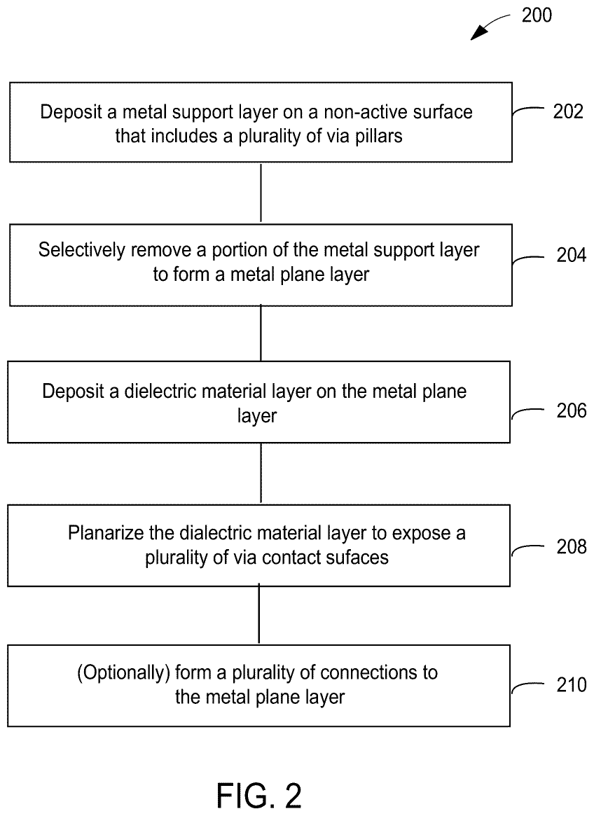

FIG. 2 is a block diagram of a method 200 that may be used to redistribute lateral polishing forces across a surface of a support layer while concurrently forming an electrical contact or thermal spreader plane for use in a stacked device assembly. FIGS. 3A-3E are cross-sectional views of the substrate 100 that schematically illustrate various aspects of the method 200, according to some embodiments.

The method 200 generally includes forming a support layer stack 322 (FIG. 3C) on the non-active surface 104 of the substrate 100 (post-TSV reveal) and planarizing a surface of the support layer stack 322 to expose a plurality of via contact surfaces 312 (FIG. 3D). As described above in relation to FIG. 1F, the non-active surface 104 may include a plurality of via pillars 126 and one or more dielectric layers 128 disposed on the plurality of via pillars 126 and on portions of a recessed surface 124 disposed therebetween. Forming the support layer stack 322 respectively includes forming a metal plane layer 306 (FIG. 3B) and depositing a dielectric support layer 308 (FIG. 3C) on the metal plane layer 306.

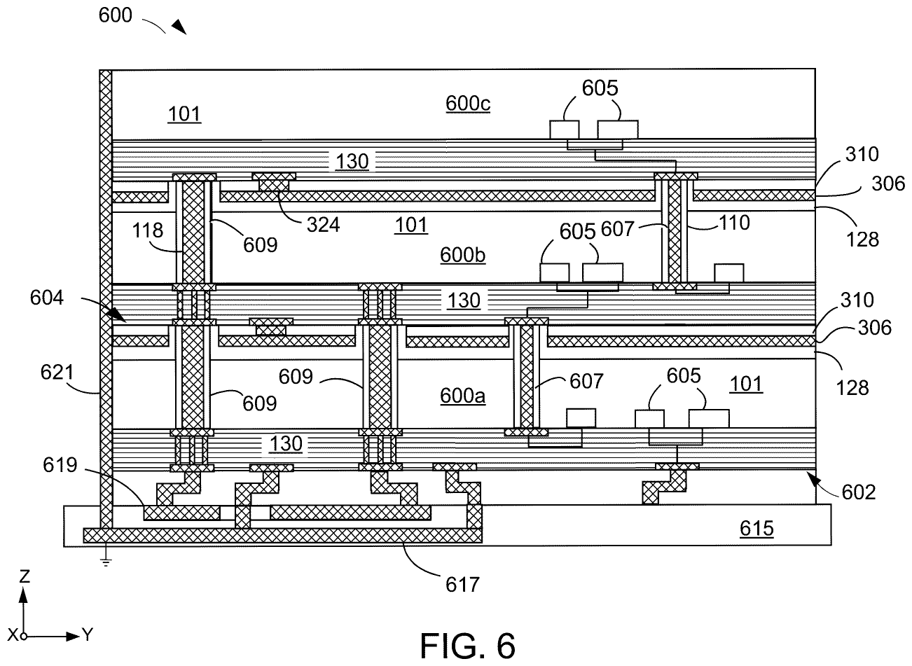

At block 202, the method 200 includes depositing a metal support layer 304 (FIG. 3A) on the non-active surface 104 of the substrate 100. In some embodiments, the metal support layer 304 is formed of an electrically and/or thermally conductive material, such as a metal or metal alloy. In some embodiments, the metal support layer 304 is formed of an electrically conductive material suitable for use as a power plane 619 or ground plane 617 in a power distribution network of a stacked-device assembly, such as the device assembly illustrated in FIG. 6.

Examples of materials that may be used to form the metal support layer 304 include the example materials set forth above in relation to the conductive material 116. In some embodiments, the metal support layer 304 is formed of the same or a similar metal composition as the conductive material 116. In some embodiments, the metal support layer 304 may be formed directly on the dielectric material layer 128, i.e., without the use of a barrier or adhesion film layer therebetween. In some embodiments, the metal support layer 304 may be formed using a chemical vapor deposition (CVD) process, a physical vapor deposition (PVD) process, or a combination thereof. In some of those embodiments, the metal support layer 304 may be formed by depositing a conductive seed layer (not shown), e.g., a metal or metal alloy, on the dielectric material layer 128, e.g., a CVD or PVD deposited seed layer, and depositing the bulk material of the metal support layer 304 on the seed layer using an electrodeposition process. The seed layer may be formed of a different or a substantially similar composition of materials as the bulk material. In other embodiments, the method 200 may include depositing one or more barrier or adhesion layers (not shown) on the dielectric material layer before depositing the metal support layer 304. Examples of suitable materials that may be used as the barrier or adhesion layers include silicon nitrides, titanium, titanium nitrides, tantalum, tantalum nitrides, tungsten nitrides, titanium silicon nitrides, tantalum silicon nitrides, tungsten silicon nitrides, and combinations thereof.

At block 204, the method 200 includes selectively removing a portion of the metal support layer 304 to form a metal plane layer 306 (FIG. 3B). Removing the portion of the metal support layer 304 recesses a surface 318 below an upper surface of the end portion 316 of the via pillar 126 (FIG. 3B). The remaining portion of the metal support layer 304 forms the metal plane layer 306, which surrounds at least the base portions 314 of the via pillars 126 and is disposed on the recessed surfaces 124 therebetween. Here, the base portions 314 of the via pillars 126 are adjacent to the recessed surface 124, and the end portions 316 are spaced apart from the recessed surface 124 by the base portions 314.

The metal plane layer 306 may be formed at block 204 using a selective material removal process suitable for planarizing the metal support layer 304 without removing the portions of the dielectric material layer(s) 128 disposed over the via pillars 126. In some embodiments, the surface 318 may be recessed using an etching process that etches a portion of the metal support layer 304 but removes relatively little of the dielectric material layer 128. In those embodiments, at least a portion of the dielectric material layer 128 remains over the surfaces of the via pillars 126. In some embodiments, the etch process is a planarizing etch process using liquid etchants, such as a spin etch process. In some embodiments, the surface 318 may be recessed using a highly selective CMP process, such as by using a selective metal polishing slurry typically used in a metal damascene process. In some embodiments, the CMP process may use relatively low polishing forces and/or a relatively soft polishing pad (when compared to a CMP process typically used for dielectric material planarization) so as to avoid pillar breakage that might otherwise result from lateral forces exerted during a more aggressive CMP process.

As shown in FIG. 3B, the metal plane layer 306 forms a continuous electrically and/or thermally conductive material layer across the non-active surface 104 of the substrate 100. A discontinuous plurality of openings are defined in the metal plane layer 306, where each of the plurality of openings has a corresponding via pillar 126 that extends upwardly therethrough. Thus, in some embodiments, the metal plane layer 306 is formed to surround the base portions 314 of the individual via pillars 126 in the X-Y plane. In some embodiments, at least a portion of the dielectric material layer 128 disposed on the sidewalls of the via pillars 126 remains after the CMP process so that the conductive via features 118 are electrically isolated from the metal plane layer 306 by portions of the dielectric material layers 110 and 128 disposed therebetween.

In some embodiments, the metal plane layer 306 has a thickness between about 0.1 um and about 5 um, such as about 0.1 um to about 3 um. In some embodiments, the via pillar 126 extends above the surface 318 of the metal plane layer 306 (in the Z-direction) by a height H2 of about 0.25 um or more, such as about 0.5 um or more, e.g., in the range from about 0.25 um to about 5 um.

At block 206, the method 200 includes depositing a dielectric support layer 308 on the metal plane layer 306 and the via pillars 126 extending therethrough. Examples of materials that may be used to form the dielectric support layer 308 can be found above in the example materials for the dielectric material layers 110 and 118. The dielectric support layer 308 and the metal plane layer 306 disposed there beneath each surround the sidewall portions of the individual via pillars 126 in the X-Y direction. As shown, the dielectric support layer 308 is deposited to a thickness that surrounds the length of the end portions 316 in the X-Y directions. In some embodiments, the dielectric support layer 308 is deposited to a thickness of about 0.1 um or more, for example between about 1 um and about 5 um, or about 1 um or more, such as between about 1 um and about 5 um.

At block 208, the method 200 includes using a CMP process to remove a portion of the dielectric support layer 308 and the upwardly facing portions of the via pillars 126 disposed therein to form a dielectric plane layer 310. Here, the dielectric plane layer 310 is the portion of the dielectric support layer 308 that remains following the CMP process. As shown, the backside surface 320 further includes a plurality of via contact surfaces 312 disposed through the dielectric plane layer 310 and coplanar therewith or slightly recessed therefrom. The CMP process at block 208 may include any process suitable for planarizing the dielectric material layer and may be substantially similar to CMP processes used to planarize interlayer dielectrics materials, such as tetra-ethyl-ortho-silicate (TEOS) deposited oxides, in a BEOL CMP process.

At block 210, the method 200 optionally includes forming a plurality of metal plane connection pads 324 (FIG. 3E) in the backside surface that may be used as an inter-device connection between the ground plane 617 and an adjacent device in a stacked device assembly, such as described below in relation to FIG. 6. The connection pads 324 may be formed of any suitable conductive material, such as any of the example metals and metal alloys described above for the conductive material 116 and metal support layer 304. In some embodiments, the connection pads 324 are formed of substantially the same material as the metal plane layer 306. In some embodiments, the connection pads 324 are formed by a damascene process, e.g., by patterning the dielectric plane layer 310, depositing a metal layer (not shown) on the patterned surface, and removing an overburden of the metal layer from the field of the dielectric material layer. In other embodiments, the connection pads 324 may be formed by patterning the dielectric support layer 308 and depositing the connection metal before the CMP process at block 208. In those embodiments, the CMP process used at block 208 may include a plurality of polishing stages, such as a first stage to remove an overburden of the connection metal and a second stage to form the backside surface 320.

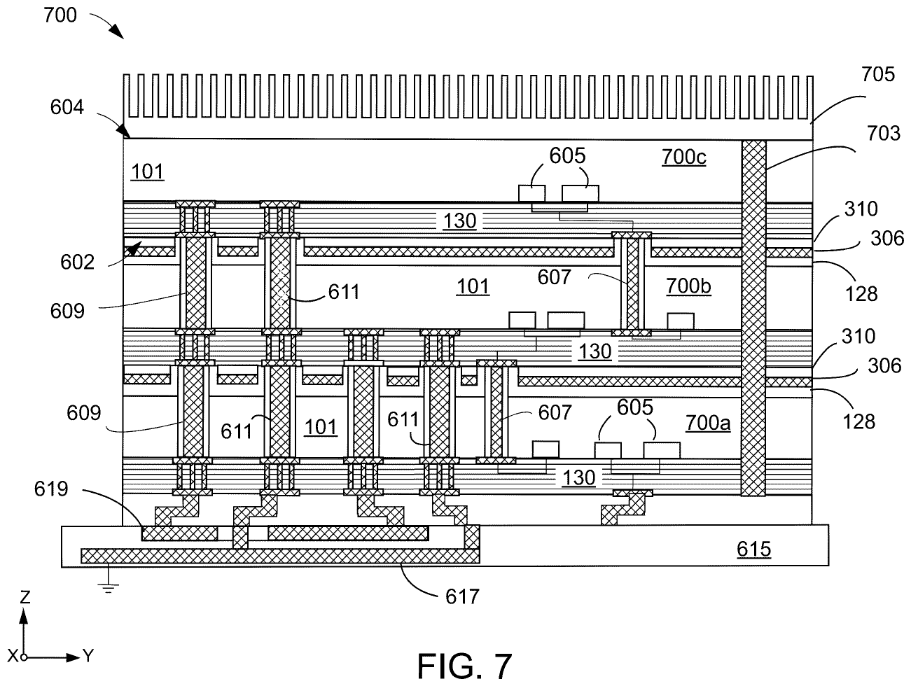

In some embodiments, the metal plane layer 306 may be used to tune the cumulative stress of the material layers deposited on the active and non-active surface 104 in order to control bow and warp of the substrate. Typically, the metal layers, e.g., the metal plane layer 306 have an intrinsic tensile stress, and dielectric material layers have an intrinsic compressive stress. In some embodiments, the thickness of the metal plane layer 306, may be selected to offset compressive stresses in already deposited or to-be-deposited material layers. In some embodiments, the metal plane layer 306 may be deposited to a thickness that provides a substantially stress-neutral structure after the contact surfaces 312 are formed, thus reducing undesirable stress-related warp and bow of the substrate 101 and/or individual devices formed therefrom. In some embodiments, the thickness of the metal plane layer 306 may be adjusted to the bow and warp to within processing limits suitable for direct bonding surfaces of different devices, such as described below in relation to FIGS. 6-7.

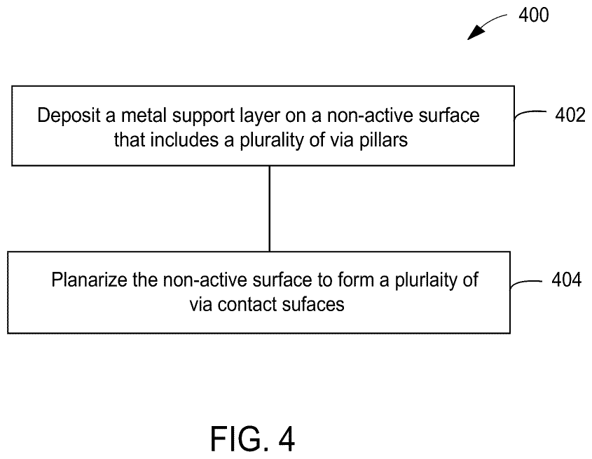

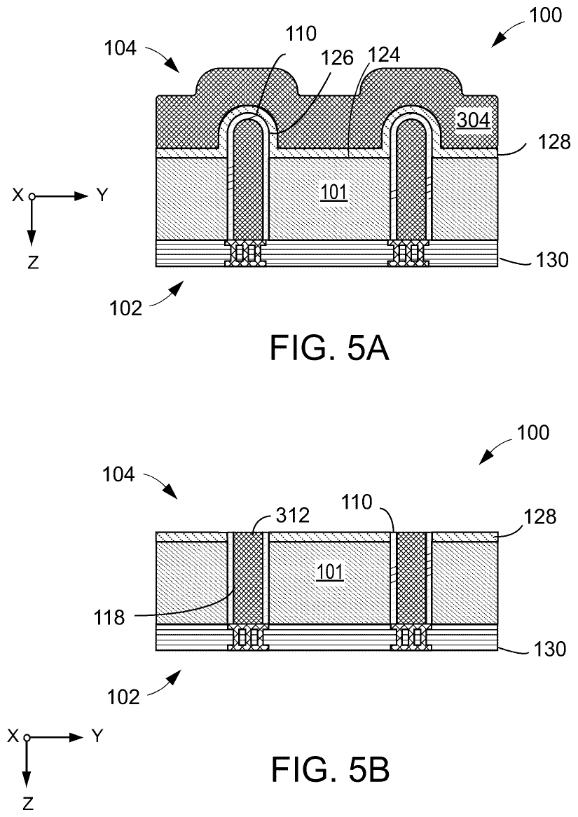

FIG. 4 is a block diagram of a method 400, according to another embodiment, that may be used to substantially reduce CMP-related pillar breakage and/or cracking when forming a metal plane layer is not desired. FIGS. 5A-5B are cross-sectional views of a substrate 100 that schematically illustrate various aspects of the method 400, according to some embodiments. The method generally includes depositing a metal support layer 304 on the non-active surface 104 following TSV reveal and concurrently removing the metal support layer 304 and the plurality of via pillars 126 using a planarizing CMP process.

At block 402, the method includes depositing a metal support layer 304 on the non-active surface 104 of a substrate following a TSV reveal process. As described above in the method 200 and in relation to FIG. 1F, the non-active surface 104 following TSV reveal generally includes a plurality of via pillars 126 extending upwardly from the recessed surface 124, and one or more dielectric layers 128 disposed on the plurality of via pillars 126 and the recessed surface 124. The one or more dielectric layers 128 provide an isolation layer and/or diffusion barrier that protects the recessed surface 124 of the semiconductor substrate 101 from undesired contamination and or material diffusion from the metal support layer 304. In some embodiments, the metal support layer 304 is formed directly on the dielectric material layer without the use of a barrier and/or adhesion material layer. In other embodiments, the method 400 includes depositing one or more barrier and/or adhesion layers (not shown) on the dielectric material layer before depositing the metal support layer 304. Examples of suitable materials that may be used as the barrier and/or adhesion layers are described above in relation to the method 200. In some embodiments, the metal support layer 304 is deposited to a thickness that is greater than the height H1 of the via pillars 126, such as shown in FIG. 5A, so that the metal support layer 304 surrounds each of the via pillars 126 along its length, i.e., in the Z-direction.

At block 404, the method 400 includes concurrently removing the metal support layer 304 and the via pillars 126 disposed therein using a planarizing CMP process. In some embodiments, the metal support layer 304 and the plurality of via pillars 126 are concurrently removed using a low selectivity CMP process that simultaneously planarizes the surface of the metal support layer 304 and the upwardly facing surfaces of the via pillars 126 disposed therein. For example, in some embodiments, the CMP process has a material removal rate selectivity of between 3:1 and 1:3 for the metal of the metal support layer 304 and one or more or each of the materials forming the dielectric material layers 128, such as between about 2:1 and 1:2, between about 3:2 and 2:3, between about 4:3 and about 3:4, between about 5:4 and about 4:5, or about 1:1. In embodiments where the dielectric material layers 128 comprises a silicon oxide layer and a silicon oxide layer the CMP process may have material removal rate selectivity of between about 2:1 and about 1:2, such as between about 3:2 and 2:3, between about 4:3 and about 3:4, or between about 5:4 and about 4:5, or about 1:1.

In some embodiments, the metal support layer 304 and the plurality of via pillars 126 are concurrently removed using two or more different selective polishing processes in an alternating sequence that includes removing a portion of the metal support layer 304 and portions of the via pillars 126. For example, the sequence may include an alternating sequence of a metal selective CMP process and a dielectric selective CMP process. The metal selective process may have a higher material removal rate for the metal support layer 304 than the dielectric material layer 128, and the dielectric selective process may have a higher material removal rate for the dielectric material layer 128. In those embodiments, the alternating sequence may be repeated until the metal support layer 304 is removed from the field surface of the dielectric layer(s) 128 and the via contact surfaces 312 of the via features disposed therein are substantially coplanar with or slightly recessed below the field surface.

The embodiments described above in relation to FIGS. 2 and 4 may be advantageously used to significantly reduce CMP-related breakage and/or cracking of the via pillars 126 during post-reveal processing. The support layers used in each of the methods redistribute lateral polishing forces from the individual via pillars 126 to the larger surface area of the support layer surrounding the via pillars 126 while concurrently providing mechanical support to the via pillars 126 in the X-Y directions. During the CMP processes described above in blocks, the polishing forces are distributed across the surface of the support layers at the polishing interface thus reducing the shear stress that would otherwise be imparted to an exposed via pillar sidewall were the support layers not present. The lateral support is provided by the support layer(s) that surround the via pillars 126 in the X-Y plane to provide a mechanical counterforce, e.g., a brace, against the lateral polishing forces exerted on the via pillars 126, thus reducing the moment caused at the stress points 129 (FIG. 1F).

By redistributing the polishing forces and concurrently providing lateral support to the TSV pillars 126, the incidence of pillar breakage and or cracking can be substantially reduced independent of the pillar height. Thus, the above-described methods may be used advantageously to increase the amount of material removed from the semiconductor substrate during the selective material removal process, as shown in FIG. 1E, without increasing the incidence of defects associated therewith. This increased processing window can be used to accommodate unknown variations in the depth of the blind vias formed in a via-first or via-middle process.

FIGS. 6-7 are schematic cross-sectional views of example device assemblies, e.g., three-dimensional integrated circuits (3D-ICs), that may be formed using the methods described above. As shown, each of the device assemblies includes a plurality of devices that are stacked on one another in a face-to-back bonding integration scheme. In other embodiments, the device assemblies may be formed using face-to-face bonding schemes or a combination of face-to-back and face-to-face bonding integration schemes. In some embodiments, the active and non-active dielectric and/or metal surfaces of the individual devices are direct-bonded to one another in an adhesive-free wafer-to-wafer, chip-to-wafer, or chip-to-chip assembly process. Examples of suitable direct-bond technologies that may be used to form the device assemblies include DBI® (direct bond interconnect) or ZiBond® direct interconnect technologies, which are commercially available from Xperi Holding Corp., San Jose, California. Other embodiments of the device assemblies illustrated in FIGS. 6-7 may be formed using any suitable direct, hybrid, or conventional method that forms electrical connections between the TSV features, connection pads, and/or metal plane contacts of the individual devices.

In FIG. 6, the device assembly 600 includes a plurality of devices 600a-c disposed in a stacked arrangement and direct-bonded to one another in a face-to-back bonding integration scheme. As shown, each of the devices 600a-c includes a semiconductor substrate 101 having an active side 602 and an opposite non-active side 604. In FIG. 6, the active sides 602 are shown in a face-down orientation and each includes device elements 605, e.g., transistors, capacitors, resistors, and/or other active components formed therein or thereon. The devices 600a-c each include a plurality of metal interconnect layers 130 disposed on the active side 602 where the metal interconnect layers 130 comprise local and global interconnects used to connect the device elements 605 to one another and to circuits external to the devices 600a-c, e.g., to other devices in the device assembly 600. The base device 600a and middle device 600b in the device assembly 600 each include a plurality of TSV features 118 formed through the semiconductor substrate 101 in a via-first or via-middle fabrication process.

Here, the TSV features 118 include signal TSVs 607 and power TSVs 609. The signal TSVs 607 communicatively connect the individual device elements 605 to one another and/or to external circuits to facilitate the exchange of information therebetween. The power TSVs 609 connect each of the individual devices to a power plane 619 or a ground plane 617 of a power delivery network (PDN) 615. Here, the vertical arrangement of the devices 600a-c, and the shorter connection paths provided by the signal TSVs 607 disposed therethrough, substantially reduce data transmission times between the active components of each of the devices. The shorter data transmission paths thus provide faster processing speeds and reduced power consumption when compared to other data transmission methods, such as wire bond interconnects.

The power TSVs 609 are generally larger in diameter than the signal TSVs 607 in order to accommodate higher current flow therethrough, e.g., by decreasing resistance of the power delivery path. The relatively large size of the power TSVs 609 means they occupy valuable surface area within the individual devices 600a-c with lower devices 600a having larger areas dedicated to power TSVs 609 than upper devices 600b, i.e., to accommodate a direct power delivery path from the power plane 619 to each device positioned thereabove. Despite the relative difference in sizes between power TSVs 609 and signal TSVs 607, a power TSV 609 typically has a smaller cross-sectional area than that of other power delivery connections, such as traces or wire bonds. Thus, the resistance per unit length of a series of power TSVs 609 used to connect a power supply to an upper device in a multi-device stack can cause substantial power dissipation, undesirable generation of heat, and undesirable voltage variations between devices.

The device assembly 600 shown in FIG. 6 provides a current path, e.g., a ground connection path, through one or more metal plane layers 306 formed on corresponding non-active surfaces of the individual devices 600a-b, according to the methods described above. Each of the upper devices 600b-c is connected to a metal plane layer 306 formed on the non-active side 604 of the device below, e.g., through the plurality of connection pads 324, and the metal plane layer 306 is connected to the ground plane 617 using an external connection path 621, such as a side trace or a plurality of wire bond connections (not shown). The metal plane layers 306 may be used advantageously to reduce the number of power TSVs 609 and/or increase the current capacity of the power delivery network 615 while concurrently reducing power consumption. In other embodiments, the device assembly includes a plurality of ground TSVs 611 connected to the ground plane 617, as illustrated in FIG. 7, and the metal plane layers 306 are connected to the power plane 619 through the external connection path 621.

In some embodiments, one or more of the metal plane layers 306 may be used as a bias plane configured to provide an independently controllable bias voltage to a device positioned thereabove. In one example, one or more of the metal plane layers are electrically connected to an independently controllable bias voltage generator configured to provide a bias voltage thereto. In some embodiments, such as illustrated in FIG. 7, one or more of the metal plane layers 306 may be used as a thermal spreader that redistributes heat generated and/or concentrated in local areas of the active surface 602 disposed above or below the metal plane layer 306.

FIG. 7 is a schematic cross-sectional view illustrating a device assembly 700 featuring a plurality of devices 700a-c disposed in a stacked face-to-back arrangement. Power is delivered to each of the devices 700b-c through power TSVs 609 and ground TSVs 611 formed through each of the lower devices 700a-b, where the power TSVs 609 are connected to the power plane 619 and one or more ground TSVs connected to the ground plane 617. Here, each of the metal plane layers 306 of devices 700a-b are configured for use as thermal spreaders to redistribute heat generated from the corresponding device and/or the active surface 602 of the adjacent device (disposed thereabove). As shown, each of the metal plane layers 306 are in thermal communication with a thermal TSV (TTSV) 703, e.g., a via-last TSV formed of a thermally conductive material, that connects the metal plane layers 306 with a cooling system, such as a heat sink 705. The inter-device thermal spreader may be advantageously used to remove heat from between devices in a stacked device assembly, thus potentially increasing the number of devices that can be included in such an arrangement.

The methods, devices, and device assemblies discussed above are intended to be illustrative and not limiting. One skilled in the art would appreciate that individual aspects of the methods discussed herein may be omitted, modified, combined, and/or rearranged without departing from the scope of the invention. For example, in some embodiments, a device assembly may include one or more metal plane layers 306, each configured for use as an inter-device ground or power plane, such as illustrated in FIG. 6, and one or more metal plane layers 306 configured for use as a thermal spreader, such as illustrated in FIG. 7. More generally, the above disclosure is meant to be exemplary and not limiting. Only the claims that follow are meant to set bounds as to what the present invention includes.

What is claimed is:

1. A method for forming a conductive plane around a via pillar that protrudes from a surface of a substrate, comprising:
forming a support layer stack comprising a metal plane layer that surrounds at least a base portion of the via pillar and a first dielectric layer disposed on the metal plane layer that covers an upwardly facing surface of the via pillar; and
removing, by use of a polishing process, a portion of the first dielectric layer and a portion of the via pillar to expose a surface of the metal via surrounded by a remaining portion of the first dielectric layer.

2. The method of claim 1, wherein one or more second dielectric layers are disposed between the metal plane layer and the non-active surface of the substrate and between the metal plane layer and the base portion of the via pillar.

3. The method of claim 2, wherein the substrate comprises a semiconductor portion, the metal via extends through the semiconductor portion, and a dielectric liner is disposed between the metal via and the semiconductor portion and between the metal via and the one or more second dielectric layers.

4. The method of claim 1, wherein the metal support layer comprises copper, tungsten nickel, or a combination thereof.

5. The method of claim 1, wherein forming the metal plane layer comprises depositing a metal support layer and recessing a surface of the metal support layer below the upwardly facing surface of the via pillar.

6. The method of claim 1, wherein recessing the surface of the metal layer comprises removing a portion of the metal layer by use of a polishing process, an etch process, or a combination thereof.

7. The method of claim 1, wherein the metal plane layer forms a ground or power plane of a power distribution network to two or more interconnected devices.

8. A method of forming uniform through-substrate vias in a microelectronic device, comprising:
depositing a support layer to surround a plurality of via pillars protruding from a surface of a substrate, wherein the support layer is deposited to a thickness that is greater than a height of the plurality of via pillars; and
exposing an upwardly facing surface of each of the through-substrate vias by removing the support layer and the plurality of via pillars.

9. The method of claim 8, wherein the support layer is formed of a metal.

10. The method of claim 9, wherein the metal is copper, tungsten, nickel, or a combination thereof.

11. The method of claim 10, wherein the exposed surface comprises the metal.

12. The method of claim 9, wherein the support layer is removed using a polishing process.

13. The method of claim 12, wherein the polishing process has a removal rate selectivity of between about 2:1 and 1:2 for the respective materials forming the support layer and the via pillars.

14. A microelectronic structure comprising:
a semiconductor substrate having a first surface and a second surface opposite the first surface;
a first dielectric layer disposed on the first surface;
a via structure disposed through the first dielectric layer and at least partially disposed through the semiconductor substrate, wherein at least a portion of the via structure protrudes above the first dielectric layer to define a via pillar;
a metal plane layer disposed on the first dielectric layer; and
a second dielectric layer disposed on the metal plane layer.

15. The microelectronic structure of claim 14, wherein the via structure comprises a conductive material.

16. The microelectronic structure of claim 14, wherein the conductive material of the via structure is electrically isolated from the metal plane layer by a portion of a dielectric liner disposed therebetween.

17. The microelectronic structure of claim 15, wherein the metal plane layer comprises copper, tungsten, nickel, or a combination thereof.

18. The microelectronic structure of claim 14, wherein the metal plane layer is coupled to an external power supply.

19. The microelectronic structure of claim 14, wherein the metal plane layer is coupled to a ground connection path.

20. The microelectronic structure of claim 14, wherein the metal plane layer forms a bias plane of a packaged electronic device.
